(19) United States
(12) Patent Application Publication
(10) Pub. No.: US 2004/0021517 A1
(43) Pub. Date: Feb. 5, 2004

(54) Power minimization, correlation-based closed loop for controlling predistorter and vector modulator feeding RF power amplifier

(75) Inventors: Brent Logan Irvine, San Jose, CA (US); John Eisenberg, Los Altos, CA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: Spectrian Corporation, Sunnyvale, CA

(21) Appl. No.: 10/212,320

(22) Filed: Aug. 5, 2002

(51) Int. Cl. H03F 1/26

(52) U.S. Cl. 330/151; 330/149

(57) ABSTRACT

An RF power amplifier linearizer uses a switched distortion power-minimization routine, or simultaneous correlation and power-minimization routines to adjust operational parameters of a vector modulator and a predistortion operator feeding the RF amplifier. The switched power-minimization routine controls the vector modulator, and then adjusts coefficients of the predistorter using the same power minimization routine. The continuous correlation and power minimization routine adjusts the predistortion unit by means of a power minimization unit, and uses a correlator based control mechanism to control the vector modulator simultaneously with the power minimization routine's control of the predistortion unit.

### FIELD OF THE INVENTION

The present invention relates in general to communication systems and components therefor, and is particularly directed to a relatively low cost RF power amplifier linearization architecture, that incorporates a switched power minimization-based closed loop or a pair of continuous correlation and power minimization closed loops for controlling RF signal modification units, such as a predistorter and a vector modulator, installed in the input path of the amplifier.

### BACKGROUND OF THE INVENTION

Communication service providers are subject to very strict bandwidth usage spectrum constraints, including technically mandated specifications and regulations imposed by the Federal Communications Commission (FCC). These rules require that sideband spillage, namely the amount of energy spillover outside a licensed band of interest, be sharply attenuated (e.g., on the order of 50 dB). Although these regulations may be easily met for traditional forms of modulation, such as FM, they are difficult to achieve using more contemporary, digitally based modulation formats, such as M-ary modulation, or when more than one carrier through a single amplifier is required.

Attenuating the sidebands sufficiently to meet industry or regulatory-based requirements by means of such modulation techniques requires very linear signal processing systems and components. Although relatively linear components can be implemented at a reasonable cost at relatively narrow bandwidths (baseband) of telephone networks, linearizing components such as power amplifiers at RF frequencies can be prohibitively expensive.

A fundamental difficulty in linearizing RF power amplifiers is the fact that they are inherently non-linear devices, and generate unwanted intermodulation distortion products (IMDs) that manifest themselves as spurious signals in the amplified RF output signal, such as spectral regrowth or spreading of a compact spectrum into spectral regions that do not appear in the RF input signal. This distortion causes the phase/amplitude of the amplified output signal to depart from the phase/amplitude of the input signal, and may be considered as an incidental (and undesired) amplifier-sourced modulation of the RF input signal.

An inefficient approach to linearizing an RF power amplifier is to build the amplifier as a large, high power device, and then operate the amplifier at a low power level (namely, at only a small percentage of its rated output power), where the RF amplifier's transfer characteristic is relatively linear. An obvious drawback to this approach is the overkill penalty—a costly and large sized RF device.

Other techniques include baseband polar (or Cartesian) feedback, pre-amplification, pre-distortion correction, and post-amplification, feed-forward correction. In the baseband feedback approach, the output of the amplifier is compared to the input and a baseband error signal is used to directly modulate the signal which enters the power amplifier. For pre-amplification, pre-distortion correction, a predistortion signal is injected into the RF input signal path upstream of the RF amplifier. The feed-forward approach extracts the error (distortion) present in the amplifier's output signal, amplifies the error signal to the proper level, and then reinjects complement of the error signal back into the output path of the amplifier, so that (ideally) the RF amplifier's distortion is effectively canceled.

Ideally, the predistortion signal has a characteristic that is equal and opposite to the distortion expected at the output of the high power RF amplifier, so that, upon being subjected to the distorting transfer characteristic of the RF amplifier, it will effectively cancel the output distortion. Predistortion may be made adaptive by measuring the distortion at the output of the RF amplifier and adjusting the predistortion control signal, so as to minimize the distortion of the output signal of the amplifier during real time operation. Unfortunately, the level of cancellation that will be sufficient for the predistorter to be one-hundred percent effective is unknown, and the performance of the predistorter will be limited if the residual carrier component is too high.

### SUMMARY OF THE INVENTION

In accordance with the present invention, this problem is successfully addressed in a relatively low circuit complexity and cost manner, by employing a switched distortion power-minimization routine, or a pair of continuous correlation and power-minimization routines to adjust the operational parameters of RF signal modification units in the input path to the main RF amplifier. The RF signal modification units may comprise a vector modulator and a predistortion operator. The switched power-minimization routine initially controls the operation of the vector modulator, and then switches over to adjusting the coefficients of the predistorter coupled in cascade with the vector modulator, using the same power minimization routine. Optimal minimization is achieved by iteratively adjusting the proportionality or ratio of the parameter adjustment time intervals for the two units, until a prescribed figure of merit is realize (for example, the monitored power level remains within a prescribed power minimization window for each of the vector modulator and predistorter adjustments).

The continuous correlation and power minimization closed loop routine also adjusts operational parameters of the predistortion unit by means of a power minimization unit, such as that employed in the first embodiment. However, rather than switch use of this power minimization routine between predistortion control and vector modulator control, the second embodiment uses a separate, correlator based control mechanism to control the vector modulator simultaneously with the power minimization routine's control of the predistortion unit.

### BRIEF DESCRIPTION OF THE DRAWINGS

FIG. 1 diagrammatically illustrates a first, switched power minimization embodiment of the RF power amplifier linearization scheme of the present invention; and

FIG. 2 diagrammatically illustrates a second, continuous correlation and power minimization embodiment of the RF power amplifier linearization scheme of the present invention.

### DETAILED DESCRIPTION

Before describing in detail the new and improved RF amplifier linearization mechanism in accordance with the present invention, it should be observed that the invention resides primarily in a prescribed arrangement of conventional RF communication circuits, associated digital signal processing components and attendant supervisory control circuitry, that controls the operation of such circuits and components. As a result, the configuration of such circuits components and the manner in which they interface with other communication system equipment have, for the most part, been illustrated in the drawings by readily understandable block diagrams, which show only those details that are pertinent to the present invention, so as not to obscure the disclosure with details which will be readily apparent to those skilled in the art having the benefit of the description herein. Thus, the block diagram illustrations are primarily intended to show the major components of an RF amplifier distortion correction system in a convenient functional grouping, whereby the present invention may be more readily understood.

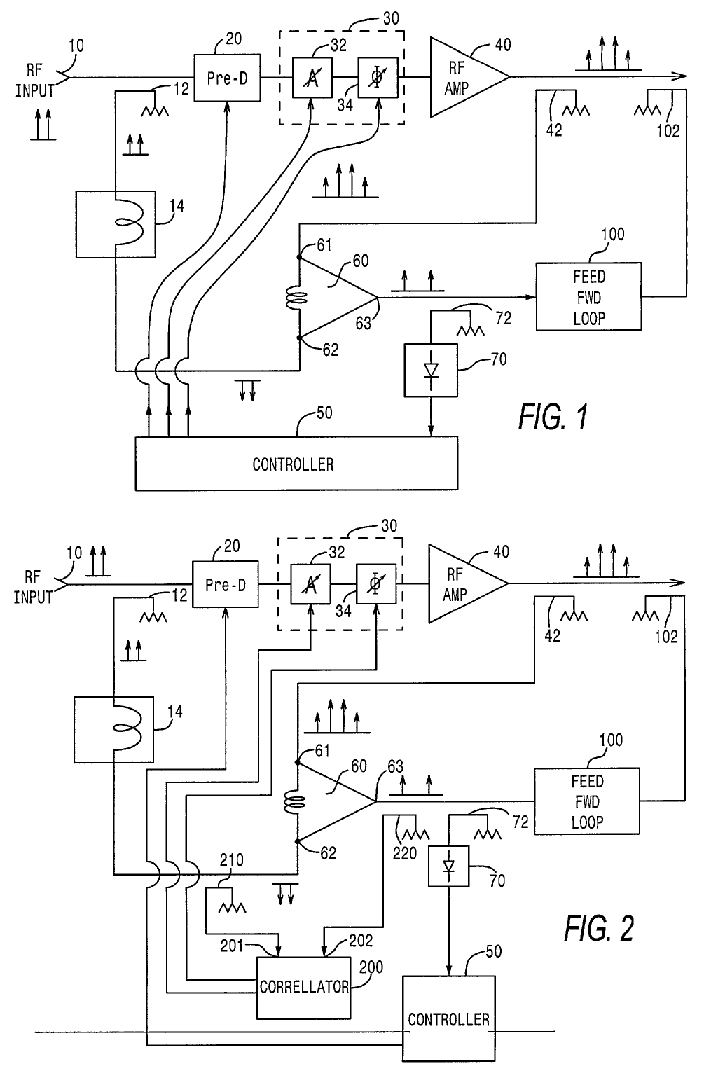

A first, power minimization-based embodiment of the RF power amplifier linearization scheme of the present invention is shown diagrammatically FIG. 1 as comprising an RF input port 10, to which a modulated RF carrier signal RFᵢₙ is supplied, input port 10 being coupled to directional coupler 12. A first, main RF amplifier path from the directional coupler is coupled through a cascaded arrangement of a predistorter unit 20 and a vector modulator 30 to a main RF amplifier 40. As a non-limiting example, the predistorter unit 20 may be of the type described in the U.S. Patent to D. Belcher et al, U.S. Pat. No. 5,760,646, assigned to the assignee of the present application and the disclosure of which is incorporated herein. It should be observed, however, that the predistorter is not limited to this implementation, and other alternative predistorter configurations may be employed. The vector modulator unit 30 contains respective, (processor-) controlled phase and amplitude elements 32 and 34. The operational parameters of the predistorter unit 20 and the vector modulator 30 are controlled by a digital processor-based controller 50.

The amplified RF output signal produced by the main RF power amplifier 40 contains the desired amplified signal plus intermodulation product based distortion components (IMDs). This amplified output signal is coupled via a directional coupler 42 over an auxiliary output path 45 to a first input 61 of a carrier cancellation combiner 60 (such as a Wilkinson splitter/combiner) within a carrier cancellation loop. Although not depicted in FIG. 1, the auxiliary output path 45 may include amplitude and/or phase adjustment components to set the parameters of the extracted component of the RF amplifier's output signal being fed to the carrier cancellation combiner.

A second input 62 of carrier cancellation combiner 60 is coupled to the RF input directional coupler 12 via a delay element 14. Delay element 14 is used to compensate for the insertion delay of the components in the main RF amplifier path. The amount of delay is such that the RF input signal sample extracted by the directional coupler 14, and presented to the second input 62 of the carrier cancellation combiner 60, is out of phase with the RF carrier component in the RF output signal sample extracted by directional coupler 42 and presented to the first input 61 of the carrier cancellation combiner 60.

With the parameters of the two inputs to carrier cancellation combiner 60 being appropriately defined, the two carrier components of these inputs will ideally mutually cancel, so that the output 63 of the carrier cancellation combiner 60 contains only the distortion products (IMDs) produced by the main RF amplifier 40. The carrier cancellation combiner output 63 may be coupled to an error amplifier path of a conventional feed-forward distortion cancellation loop 100 for reinjection into the output path from the main RF amplifier 40 via directional coupler 102, installed downstream of directional coupler 42.

In order to control the operation of the predistortion unit 20 and the vector modulator 30, the output of the carrier cancellation combiner 60 is monitored by an RF power detector 70 for the presence of unwanted noise and distortion components (IMDs). For this purpose, the RF power detector 70 may comprise a relatively inexpensive diode detector that is coupled to the output 63 of the carrier cancellation combiner by way of a directional coupler 72. With the carrier component in the output of the RF amplifier having been removed by the carrier cancellation combiner, RF power detector 70 produces an output voltage that is proportional to detected distortion power, and is coupled to controller 50.

As described briefly above, in accordance with the first embodiment of the present invention, controller 50 executes an alternating predistortion and vector modulator parameter control routine, that selectively adjusts each of these two front end preadjustment units (20 and 30) on an individual basis, until monitored IMD output power for each adjustment is minimized. In particular, during a first, vector modulator control interval, the controller 50 adjusts only the vector modulator 30 in an effort to minimize the output voltage from power detector 70.

To this end, controller 50 may employ a standard error minimization (e.g., power or least mean squared minimization) algorithm that adjusts the vector modulator amplitude and phase elements 32 and 34, respectively, until the detected (IMD associated) power is minimized. Once the voltage produced by the power detector 70 has been minimized (indicating that the IMD power is ostensibly minimal), further adjustment of the amplitude and phase parameters of the vector modulator 30 is terminated, and the controller 50 then switches to a second power control mechanism.

This second power control mechanism may also comprise a standard error power or least mean squared minimization algorithm, and is used to adjust only the predistortion unit 20 to further reduce the magnitude of the output voltage produced by power detector 70. Again, once the output of power detector 70 has been minimized during the second control interval, controller 50 switches back to further adjustment of the vector modulator 30, as described above.

The controller 50 continues to switch between the two power minimization and parameter adjustment routines, to further reduce, to the extent possible, the output voltage from the power detector 70. Optimal minimization is achieved by iteratively adjusting the proportionality or ratio of the two adjustment time intervals, until the monitored power detector voltage remains within a prescribed minimization window over for each of the vector modulator and predistortion adjustments. Once this minimum level has been reached, the controller will maintain those intervals for the respective adjustments. However, should the monitored power level exceed the minimization window, the controller again returns to a variation of the proportionality of the monitoring and adjustment intervals, until the monitored power level again is within a prescribed minimization window over for each of the vector modulator and predistortion adjustment intervals.

FIG. 2 diagrammatically illustrates a second, correlation and power minimization embodiment of the RF power amplifier linearization scheme of the present invention, in which the vector modulator unit 30, rather than being controlled so as to minimize the output of the power detector 70, is controlled by a correlator unit 200. As in the first embodiment, controller 50 may execute a standard error power or least mean squared minimization to adjust the parameters of the predistorter unit 20 and thereby minimize the monitored voltage output of the power detector 70. However, rather than being controlled in an alternating or switched manner, as in the first embodiment, the operational parameters of the predistorter unit 20 are continuously controlled by controller 50.

In order to control the operational parameters of the amplitude and phase parameters of the vector modulator unit 30, the correlator unit 200 has a first input 201 coupled to a directional coupler 210 installed between delay element 14 and the second input 62 of the carrier cancellation combiner 60. Correlator unit 200 also has a second input 202 coupled to a directional coupler 220 installed between the output 63 of the carrier cancellation combiner 60 and the directional coupler 72, to which the power detector 70 is coupled.

As such, correlator unit 200 correlates the input power sample extracted by the directional coupler 210 and the cancellation combiner power sample (representative of residual carrier power after cancellation) as extracted by the directional coupler 220. Like controller 50, correlator 200 operates in a continuous mode, adjusting the amplitude and phase parameters of the vector modulator unit 20, so that distortion energy minimization is effectively achieved on a continuous basis. Namely, in the second embodiment, the two control mechanisms (vector modulator parameter adjustment and predistortion parameter adjustment) operate simultaneously and continuously, rather than in an alternating fashion, using separate (correlation and power minimization) control loops. There is no switching between two separate monitor and control routines, as in the first embodiment.

As will be appreciated from the foregoing description, the present invention takes advantage of components such as power detectors customarily present in an RF power amplifier, to realize a relatively low cost and reduced complexity power-minimization based linearization scheme for linearizing the amplifier. A first embodiment uses a switched distortion power-minimization routine to alternatively control the operation of a vector modulator, and coefficients of a predistorter coupled in cascade with the vector modulator, using the same power minimization routine. A second embodiment controls both units simultaneously, by means of a continuous correlation and power minimization closed loop routine that adjusts operational parameters of the predistortion unit, and a correlator-based control mechanism to control the vector modulator.

While we have shown and described several embodiments in accordance with the present invention, it is to be understood that the same is not limited thereto but is susceptible to numerous changes and modifications as known to a person skilled in the art. We therefore do not wish to be limited to the details shown and described herein, but intend to cover all such changes and modifications as are obvious to one of ordinary skill in the art.

What is claimed:

1. An RF power amplifier comprising:
an RF input port to which an RF input signal is applied;
an RF output port from which an RF output signal is derived;
a main RF signal transport path coupled between said RF input port and said RF output port, and including a plurality of different types of RF signal modification units feeding an RF power amplifier that produces said RF output signal;
a carrier cancellation combiner coupled to said RF input port and said RF output port and being operative to effectively remove an RF carrier component from said RF output signal, producing a carrier cancellation output containing distortion components of said RF output signal associated with operation of said RF amplifier; and
a control unit that is operative to control operational parameters of said RF signal modification units in accordance with energy in said carrier cancellation output, and wherein operational parameters of at least one of said RF signal modification units are controlled by minimizing distortion component power in said carrier cancellation output.

2. The RF power amplifier according to claim 1, wherein said control unit operative to control operational parameters of each of said RF signal modification units by minimizing distortion component power in said carrier cancellation output.

3. The RF power amplifier according to claim 1, wherein said control unit operative to control operational parameters of one of said RF signal modification units by minimizing distortion component power in said carrier cancellation output, while simultaneously controlling operational parameters of another of said RF signal modification units in accordance with a correlation of said carrier cancellation output with said RF input signal.

4. The RF power amplifier according to claim 1, wherein said RF signal modification units include a predistortion unit and a vector modulator.

5. The RF power amplifier according to claim 4, wherein said control unit operative to control operational parameters of said predistortion unit and said vector modulator by minimizing distortion component power in said carrier cancellation output.

6. The RF power amplifier according to claim 4, wherein said control unit operative to iteratively adjust operational parameters of said predistortion unit and said vector modulator by minimizing distortion component power in said carrier cancellation output during associated alternate intervals of monitoring said carrier cancellation output.

7. A method of reducing distortion in an RF power amplifier having an RF input port to which an RF input signal is applied, an RF output port from which an RF output signal is derived, a main RF signal transport path coupled between said RF input and RF output ports and being adapted to couple energy contained in said RF input signal to a plurality of different types of RF signal modification units feeding an RF power amplifier that produces said RF output signal, said method comprising the steps of:
(a) coupling a carrier cancellation combiner to said RF input port and said RF output port, said carrier cancellation combiner being operative to effectively remove an RF carrier component from said RF output signal, and producing a carrier cancellation output containing distortion components of said RF output signal associated with operation of said RF amplifier; and
(b) controlling operational parameters of said plurality of different types of RF signal modification units in accordance with energy in said carrier cancellation output, such that operational parameters of at least one of said RF signal modification units are controlled by minimizing distortion component power in said carrier cancellation output.

8. The method according to claim 7, wherein step (b) comprises controlling operational parameters of multiple different types of RF signal modification units by minimizing distortion component power in said carrier cancellation output.

9. The method according to claim 7, wherein step (b) comprises controlling operational parameters of each of said different types of RF signal modification units by minimizing distortion component power in said carrier cancellation output.

10. The method according to claim 7, wherein said RF signal modification units include a predistortion unit and a vector modulator.

11. The method according to claim 10, wherein step (b) comprises iteratively controlling operational parameters of each of said predistortion unit and said vector modulator by minimizing distortion component power in said carrier cancellation output during associated alternate intervals of monitoring said carrier cancellation output.

12. The method according to claim 7, wherein step (b) comprises controlling operational parameters of one of said RF signal modification units by minimizing distortion component power in said carrier cancellation output, while simultaneously controlling operational parameters of another of said RF signal modification units in accordance with a correlation of said carrier cancellation output with said RF input signal.

13. The method according to claim 12, wherein said RF signal modification units include a predistortion unit and a vector modulator.

14. The method according to claim 13, wherein step (b) comprises controlling operational parameters of said predistortion unit by minimizing distortion component power in said carrier cancellation output, while simultaneously controlling operational parameters of said vector modulator in accordance with a correlation of said carrier cancellation output with said RF input signal.
